(19) United States
(12) Patent Application Publication
(10) Pub. No.: US 2026/0032911 A1
(43) Pub. Date: Jan. 29, 2026

(54) METHODS OF MANUFACTURING AN ELECTRONIC CIRCUIT TO INCREASE THE DEPTH OF A P-TYPE REGION OF A SILICON COLUMN DURING MANUFACTURING

(71) Applicant: Micron Technology, Inc., Boise, ID (US)

(72) Inventors: Yoshiaki Fukuzumi, Yokohama (JP); Kenichiro Nakagawa, Yokohama (JP); Pankaj Sharma, Boise, ID (US)

(21) Appl. No.: 19/247,782

(22) Filed: Jun. 24, 2025

Related U.S. Application Data
(60) Provisional application No. 63/676,515, filed on Jul. 29, 2024.

(51) Int. Cl. H10B 43/35; G11C 16/04; G11C 16/16; H10B 43/10; H10B 43/27

(52) U.S. Cl. CPC H10B 43/35; G11C 16/0483; G11C 16/16; H10B 43/10; H10B 43/27

(57) ABSTRACT

Systems and methods are disclosed including forming an alternating layer stack of an electronic circuit, the alternating layer stack comprising a plurality alternating conductive and dielectric layers; forming a set of memory cell columns in the alternating layer stack, wherein a bottom side of the set of memory cell columns is bonded to control circuitry; and doping, with a dopant, a top side of the set of memory cell columns, wherein the doping is performed by emitting the dopant toward the top side of the set of memory cell columns at a predetermined angle to form a doped region of material in each memory cell column of the set of memory cell columns

### RELATED APPLICATION

This application claims the benefit of U.S. Provisional Application No. 63/676,515, filed Jul. 29, 2024, the entire content of which is hereby incorporated by reference.

### TECHNICAL FIELD

Implementations of the disclosure relate generally to memory sub-systems, and more specifically, relate to methods of manufacturing an electronic circuit to increase the depth a of p-type region of a silicon column during manufacturing.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various implementations of the disclosure. The drawings, however, should not be taken to limit the disclosure to the specific implementations, but are for explanation and understanding only.

FIGS. 1A-1N are schematic diagrams illustrating a method of manufacturing an electronic circuit (e.g., a memory array) to increase the depth of p-type region of silicon column during manufacturing, in accordance with some implementations of the present disclosure.

FIG. 2 is a diagram showing a sideview of the electron paths through an assembly, in accordance with some implementations of the present disclosure.

FIG. 3 is a flow diagram of an example method of manufacturing an electronic circuit (e.g., a memory array) to increase the depth of p-type region of silicon column during manufacturing, in accordance with some implementations of the present disclosure.

FIG. 4A illustrates an example computing system that includes a memory sub-system in accordance with some embodiments of the present disclosure.

FIG. 4B is a block diagram of a memory device in communication with a memory sub-system controller of a memory sub-system, according to an embodiment.

### DETAILED DESCRIPTION

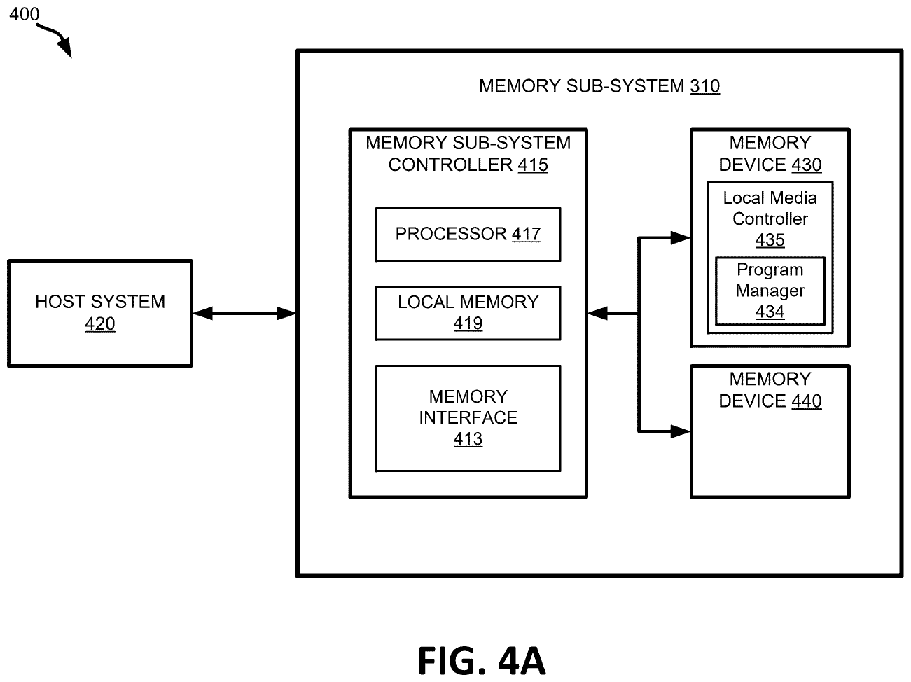

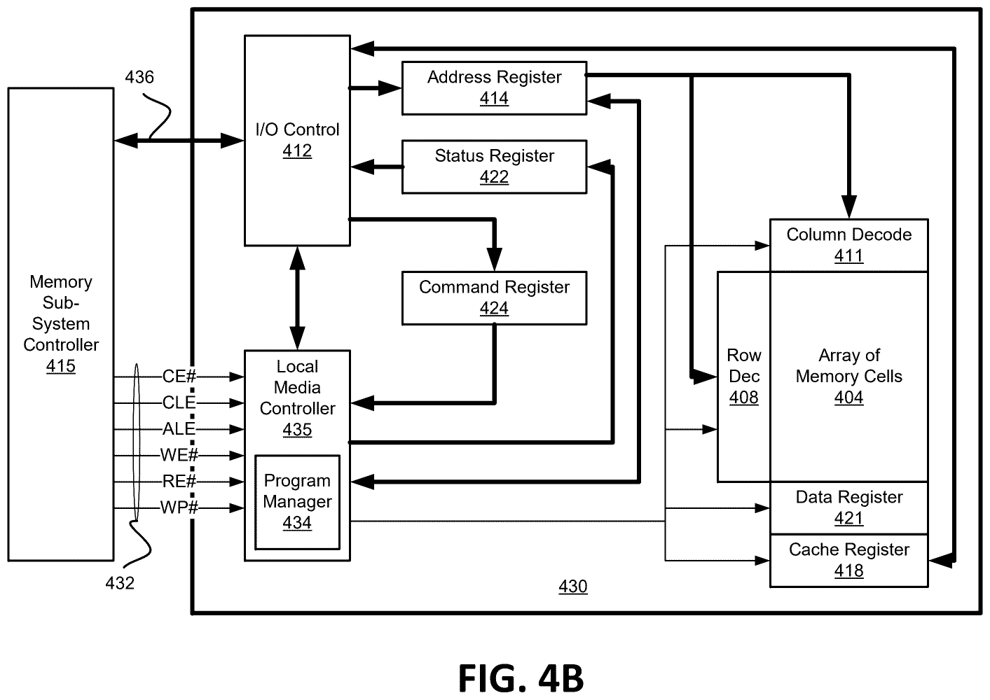

Aspects of the present disclosure are directed to methods of manufacturing an electronic circuit to increase the depth of a p-type region of a silicon column during manufacturing. The memory sub-system can be a storage device, a memory module, or a combination of a storage device and memory module. Examples of storage devices and memory modules are described below in conjunction with FIG. 4A-4B. In general, a host system can utilize a memory sub-system that includes one or more memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 4A-4B. A non-volatile memory device is a package of one or more dies. Each die can include two or more planes. For some types of non-volatile memory devices (e.g., NAND devices), each plane includes of a set of physical blocks. In some implementations, each block can include multiple sub-blocks. Each plane carries an array of memory cells formed onto a silicon wafer and joined by conductors referred to as wordlines and bitlines, such that a wordline joins multiple memory cells forming a row of the array of memory cells, while a bitline joins multiple memory cells forming a column of the array of memory cells.

Traditional NAND flash memory stores data in a two-dimensional (2D) structure, where memory cells are laid out on a single layer of dielectric material. Storage devices such as solid-state drives (SSDs) can include three-dimensional (3D) NAND flash memory technology. In particular, three-dimensional (3D) NAND stacks memory cells vertically in multiple layers which allows for increased storage densities and greater storage capacity in a comparatively smaller physical footprint when compared to two-dimensional (2D) NAND. A key advantage of 3D NAND is its ability to continue increasing storage capacities while maintaining or even improving performance and reliability. 3D NAND technology has enabled the development of SSDs with larger capacities, faster speeds, and lower costs per unit of storage.

In 3D NAND devices, a memory array can be arranged in rows (each corresponding to a wordline) and columns (each corresponding to a bitline). Each column can include a string of series-connected memory cells (e.g., non-volatile memory cells), referred to as a NAND string. Each NAND string can be selectively connected to a common source (SRC). A block of memory cells typically includes those memory cells that are configured to be erased together, such as all NAND strings sharing common wordlines.

Typically, there are two types of erase methods in 3D NAND devices, a body erase and a gate-induced drain leakage (GIDL) erase. In the body erase, NAND strings are connected to a substrate (e.g., a silicon substrate) and holes are supplied to the NAND string from the substrate, thus enabling the positive body potential required for erase. A hole refers to the lack of an electron(s) at a position where the electron(s) could exist in an atom or atomic structure, thus leading to a net positive charge at the hole's location. In the GIDL erase, the NAND strings are de-decoupled from the substrate and formed on the N+ source layer (e.g., a layer with n-type impurity) instead. During an erase operation, the electron-hole pairs are generated at the source and drain N+ junctions by a GIDL mechanism to supply holes to the NAND strings.

Some 3D NAND devices adopted a backside source connect (BSSC) architecture to simplify the source connection process, reduce costs, and improve throughput. However, due to this architecture, BSSC NAND devices lack GIDL erase capabilities and rely on body erase operations. The desire for increased storage capacities requires the columns in 3D BSSC devices to grow in length (e.g., the columns to include more series-connected memory cells), which causes the capacitance of these columns to increase. This leads to additional holes being required in the columns to perform body erase operations. However, current designs and manufacturing methods make it difficult to supply holes to the columns of BSSC NAND devices.

Aspects of the present disclosure address the above and other deficiencies by directed to methods of manufacturing an electronic circuit to increase the depth of p-type region in a sidewall of a silicon column during manufacturing. According to the aspects of the present disclosure, an alternating layer stack is formed and bonded to control circuitry. The alternating layer stack can be, for example, an ONON (oxide-nitride-oxide-nitride) stack formed by a sequence of deposition processes. The control circuitry (e.g., a complementary metal-oxide-semiconductor or CMOS device) can include an assembly used to store configuration settings (e.g., date, time, etc.), store boot sequences, etc. The stack can further include a set of columns formed by a sequence of etch processes and deposition processes. Each column can include a polysilicon channel that makes an electrical connection across a string of memory cells. The polysilicon channels can be doped with a p-type dopant (e.g., boron) to add holes to the polysilicon. Doping can refer to a process that introduces impurities (referred to as “dopants”) into a semiconductor material (e.g., silicon, germanium, etc.) to modify the semiconductor material's electrical properties. In an illustrative example, the boron can be emitted from a particular angle direction to implant the boron into the polysilicon. The boron (or any other dopant) can be emitted from the particular angle (between 30° and 45° from the top) to increase the number of holes on a particular side of each column.

Advantages of the present disclosure include, but are not limited to, increasing the number of holes in the columns of a NAND device. By increasing the number of holes, the channel potential of the columns is thereby increased, thus allowing for improved performance of body erase operations in elongated columns. Further, the increased number of holes allows for faster erase times, more flexible erase segmentations, and improved quality of service of the memory device.

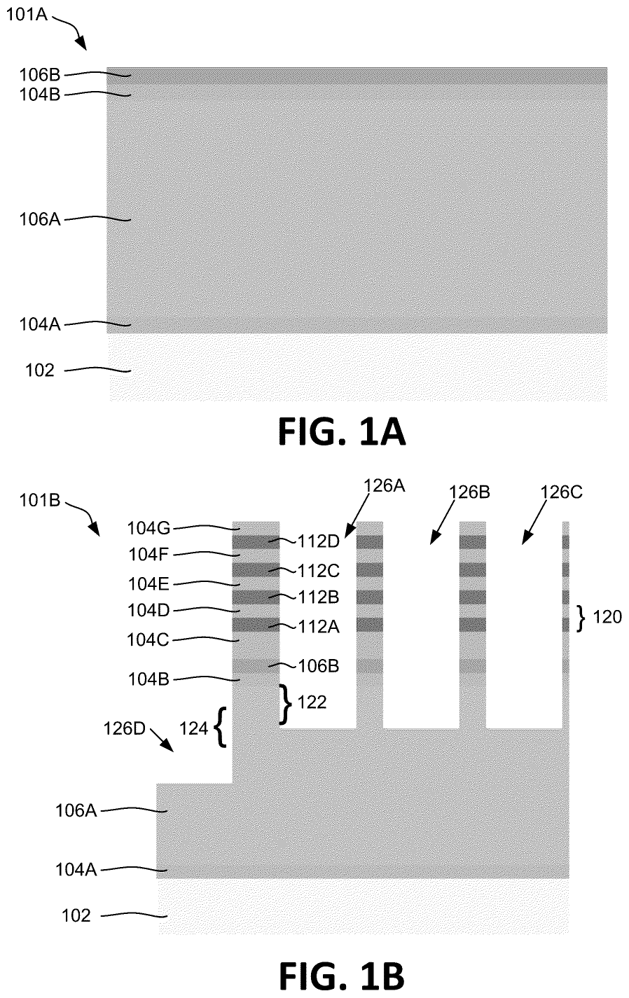

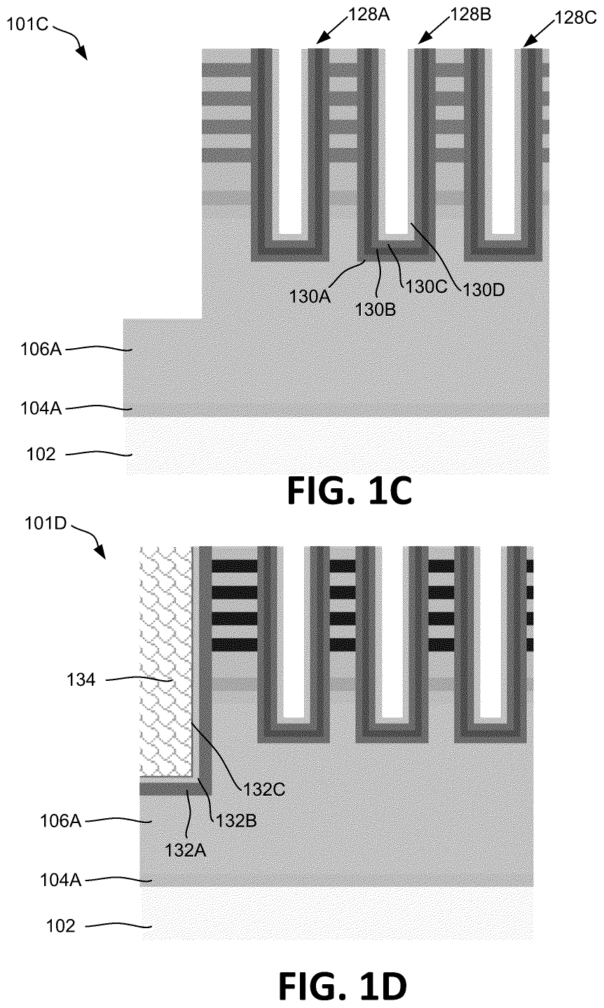

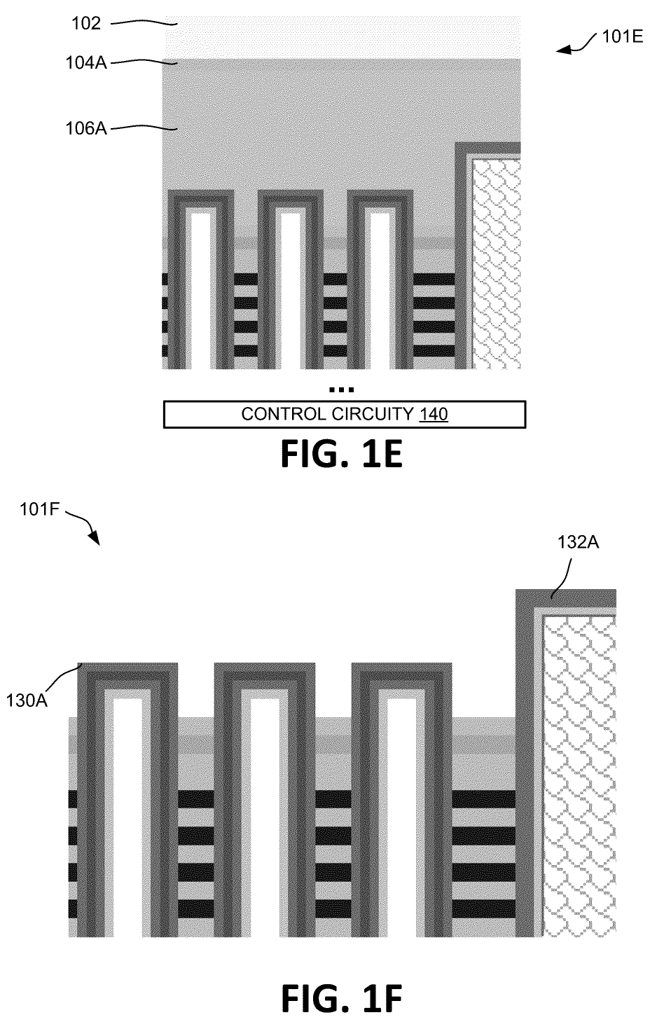

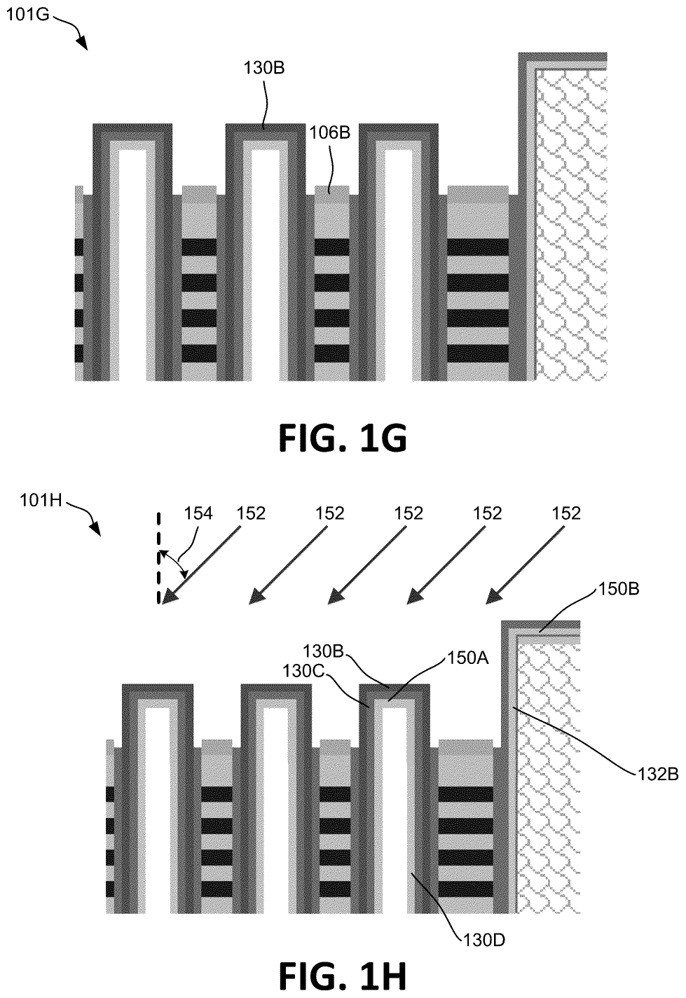

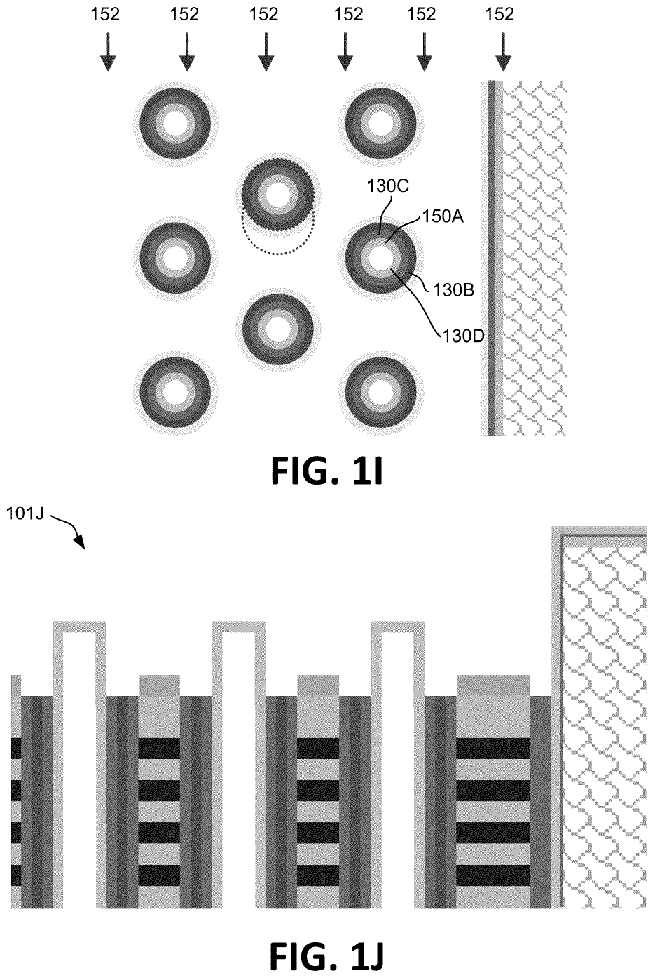

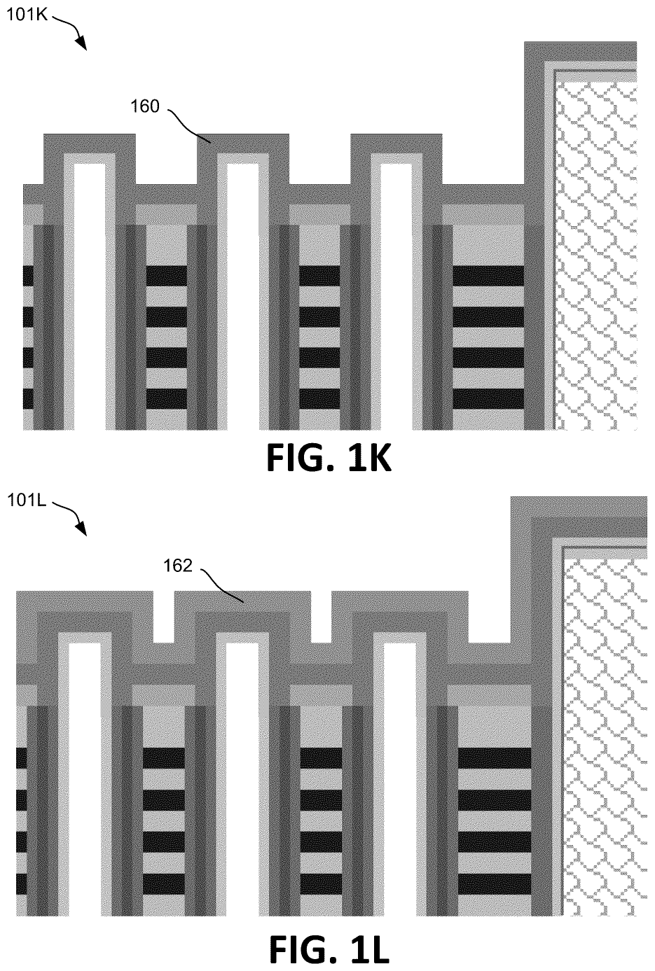

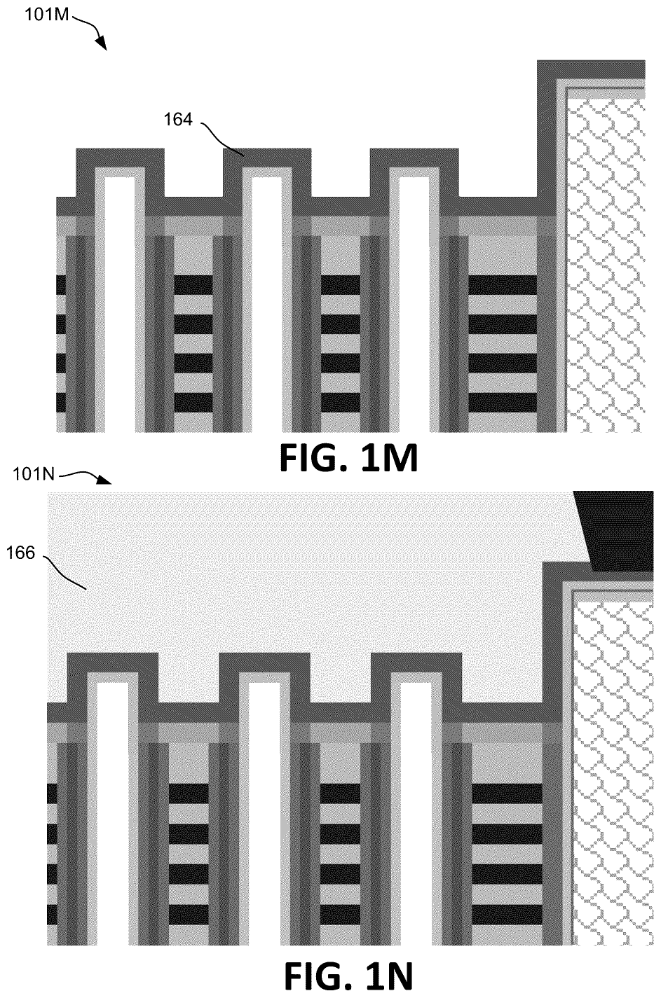

FIGS. 1A-1N are schematic diagrams illustrating a method of manufacturing an electronic circuit (e.g., a memory array) to increase the depth of p-type region of silicon column during manufacturing, in accordance with some implementations of the present disclosure. In some implementations, each of FIGS. 1A-1N illustrate a manufacturing operation for manufacturing a memory array as described herein. The different structures formed throughout the manufacturing operations of FIGS. 1A-1N can be collectively referred as an “assembly,” where the “final” assembly formed is an electronic circuit. Each manufacturing operation (hereafter “operation”) can be performed sequentially, in parallel, independently (e.g., using a different process chamber of a manufacturing device), or any combination thereof. In some implementations, the assembly formed by FIGS. 1A-1N can be a BSSC NAND device.

Referring to FIG. 1A, a representation of a first operation is shown. In some implementations, assembly 101A is formed, which can include base layer 102, oxide layers 104A, 104B (e.g., a metalloid oxide layer such as a silicon oxide layer), and polycrystalline silicon (“polysilicon”) layers 106A, 106B. In some implementations, one or more of the oxide layers 104A, 104B can include any type of dielectric layers (e.g., electrically insulating layers such as, for example, a silicon nitride layer) to electrically insulate the certain layers from each other. Base layer 102 can be a semiconductor substrate (e.g. a monocrystalline silicon substrate). In some implementations, oxide layers 104A, 104B and/or polysilicon layers 106A, 106B can be formed using one or more deposition processes. A deposition process, such as chemical vapor deposition (CVD), physical vapor deposition (PVD), is a technique in which atoms or molecules of one or more selected types are deposited on an object (e.g., a substrate), thus creating a thin layer of material on the surface of the object. In an illustrative example, a first deposition process can be performed to deposit oxide layer 104A on base layer 102, a second deposition process can be performed to deposit polysilicon layer 106A on oxide layer 104A, a third deposition process can be performed to deposit oxide layer 104B on polysilicon layer 106A, and a fourth deposition process can be performed to deposit polysilicon layer 106A on oxide layer 104B. It is noted that each layer discussed throughout this disclosure can include a particular thickness, a particular thickness gradient (e.g., changes in the thickness along a layer of the deposited film), or any combination thereof.

Referring to FIG. 1B, a representation of a second operation is shown. In some implementations, assembly 101B is formed. In particular, a tier stack having multiple tiers is formed. Each tier can be formed by multiple layers. For example, tier 120 can include an oxide layer (e.g., oxide layer 104D) and a nitride layer (e.g., nitride layer 112A). Illustrated in FIG. 1B, four tiers are shown of alternating oxide layers 104D-104G and nitride layers 112A-112D, although more tiers are possible.

In some implementations, the stack of layers is formed by multiple deposition processes. For example, a first deposition process can be performed to deposit nitride layer 112A, a second deposition process can be performed to deposit oxide layer 104D, a third deposition process can be performed to deposit nitride layer 112B, a fourth deposition process can be performed to deposit oxide layer 104E, a fifth deposition process can be performed to deposit nitride layer 112C, a sixth deposition process can be performed to deposit oxide layer 104F, a seventh deposition process can be performed to deposit nitride layer 112D, an eight deposition process can be performed to deposit oxide layer 104G, etc. The alternating layer stack can be referred to as an ONON (oxide-nitride-oxide-nitride) stack.

In some implementations, one or more etch operations are performed to remove portions of one or more oxide layers (e.g., oxide layers 104B-104G), one or more nitride layers (e.g., nitride layers 112A-112D), and/or one or more polysilicon layers (e.g., polysilicon layers 106A, 106B) from assembly 100B. In some implementations, an etch operation is performed by one or more etching agents. Such etching agents can include hydrofluoric acid (HF), phosphoric acid (H₃PO₄), hot potassium hydroxide (KOH), tetramethylammonium hydroxide (TMAH), etc. In some implementations, the etch operation is a dry etch operation performed using etch agents such as CF₄/O₂/Ar, C₄F₈/O₂/Ar, SF₆, NF₃, etc. In some implementations, the etch operation is performed until a portion of polysilicon layer 106A is removed. In some implementations, the etch operation is performed to remove different depths of material from different locations of polysilicon layer 106A (e.g., a first removed depth of material is illustrated by bracket 122 and a second removed depth of material is illustrated by bracket 124).

In some implementations, a sacrificial memory hole plug process is performed to protect the openings 126A-D created by the etch process. During the plug process, openings 126A-D can be filled with a certain material(s) (e.g., silicon, carbon, etc.) and be planarized (removing surface topologies by flattening and smoothing rough surfaces) before subsequent processes are performed.

Referring to FIG. 1C, a representation of a third operation is shown. In some implementations, assembly 101C is formed by removing (e.g., exhuming) the sacrificial plug from openings 126A-C via, for example, an etch process. One or more layers of memory cell materials are then deposited within the openings 126A-C to form a set of columns 128A-C. The memory cell materials can include one or more layers of dielectric-barrier materials, charge-blocking materials, charge-storage materials, tunneling materials (e.g., gate-dielectric materials) and channel materials, etc. In the implementation shown, the layers can include oxide layer 130A, nitride layer 130B, oxide layer 130C, and polysilicon layer 130D. In some implementations, a sacrificial memory hole plug can also be added.

Dielectric-barrier materials refers to any suitable composition used as an insulator, such as, for example, aluminum oxide, hafnium oxide, zirconium oxide, etc. Charge-blocking materials refers to any suitable composition used to reduce current leakage, such as, for example, silicon dioxide, aluminum oxide, hafnium oxide, zirconium oxide, etc. Charge-storage materials refers to any suitable composition used to store an electric charge, such as, for example, silicon nitride, silicon oxynitride, conductive nanodots, etc. Tunneling materials refer to any suitable composition used to improve data retention, endurance and program/erase speed performance, such as, for example, silicon dioxide, aluminum oxide, hafnium oxide, zirconium oxide, a laminate containing discrete layers of silicon dioxide and silicon nitride, etc. Channel materials refers to any suitable composition used for making an electrical connection across a string of memory cells, such as, for example, silicon, germanium, III/V semiconductor material (e.g., gallium phosphide), semiconductor oxide.

Referring to FIG. 1D, a representation of a fourth operation is shown. In some implementations, assembly 101D is formed by removing (e.g., exhuming) the sacrificial plug from hole 126D via, for example, an etch process. One or more layers of materials are then deposited within opening 126D. In the implementation shown, the layers can include oxide layer 132A, polysilicon layer 132B, and oxide layer 132C. A slit filler material 134 is then deposited to protect the structural integrity of the assembly. The slit filler can include, for example, a polysilicon.

Referring to FIG. 1E, a representation of a fifth operation is shown. It is initially noted that assembly 101E is shown flipped (in contrast to the assemblies 101A-101D). In some implementations, assembly 101E is formed. In some implementations, assembly 101D is coupled (e.g., bonded) to control circuitry 140. In particular, one or more of columns 128A-128C are bonded to control circuitry 140. Control circuitry 140 can include an assembled used to regulate the flow of electricity to an electronic circuit (e.g., the assembly), store configuration settings (e.g., date, time, etc.), store boot sequences, etc. An illustrative example of control circuitry includes a CMOS (complementary metal-oxide-semiconductor) device. Bonding can include a fusion bonding process, a hybrid bonding process, etc.

Referring to FIG. 1F, a representation of a sixth operation is shown. In some implementations, assembly 101F is formed performing one or more etch operations to remove substrate 102, oxide layer 104A, and polysilicon layer 106A from assembly 101E.

Referring to FIG. 1G, a representation of a seventh operation is shown. In some implementations, assembly 101G is formed performing one or more etch operations to remove oxide layer 130A and at least a portion of oxide layer 132A from assembly 101F. This will expose the nitride layer 130B and polysilicon layer 106B. In some implementations, the etch process can be, for example, a buffed oxide etch process.

Referring to FIG. 1H, a representation of an eight operation is shown, and FIG. 1I is a representation of a top view of the eighth operation. In some implementations, assembly 101H is formed by doping the polysilicon layer 130D (and 132B) with a p-type dopant, resulting in doped regions 150A and 150B. Doping can refer to any process that introduces impurities (referred to as “dopants”) into a semiconductor material (e.g., silicon, germanium, etc.) to modify the semiconductor material's electrical properties. During the doping process, a dopant is added which can function as either a donor to contribute an electron or an acceptor to create a hole with the semiconductor material that respectively generates two types of semiconductors. The first type of semiconductor is referred to as an n-type semiconductor and the second type of semiconductor is referred to as a p-type semiconductor. For n-type semiconductors, dopants such as phosphorus (P), arsenic (As), antimony (Sb), bismuth (Bi), and lithium (Li) can be used. For p-type semiconductors, dopants such as boron (B), aluminum (Al), gallium (Ga), and indium (In) can be used.

In an illustrative example, boron can be emitted from an angle direction 152 to implant the boron into the polysilicon layer 130D (and 132B). Implanting the boron can turn the semiconductor material into a conductively-doped semiconductor materials (e.g., conductively-doped silicon, conductively-doped germanium, etc.). Boron is a p-type dopant with three electrons in its valence shell. During the boron implementation process into the polysilicon material, one atom of boron can bond with four silicon atoms, thus creating a hole. This hole acts as a positive charge and attracts electrons. When an electron moves into a hole, the electron leaves a new hole in the previous position, thus allowing the material to act as a positive carrier of electrons.

The boron can be implanted via an ion implementation process. Ion implementation refers low temperature process by which ions of one element (e.g., boron) are accelerated into a solid target (e.g., polysilicon), thereby changing the physical, chemical, or electrical properties of the target. The implementation process can include, for example, plasma assist deposition (PLAD), plasma-enhanced chemical vapor deposition (PECVD), and so forth where the boron is emitted from a plasma source, an ion source, a gas source, etc.

The boron (or any other dopant) can be emitted at a particular (predetermined) angle 154 to increase the number of holes on a particular side of each column. The angle can be determined, for example, using user defined settings. Emitting the boron at an angle allows one side of the polysilicon layer 130D, 132B to be p-type doped (illustrated as doped regions 150A). In some implementations, angle 154 can be between 30° and 45° from the top. In other implementations, angle 154 can be less than 30° (e.g., between 1° and 30°) or more than 45° (e.g., between 45° and 89°). Due to the angle 154 of the projected boron and the curvature of the columns, the boron is implanted on the top crescent portion of the columns, as shown in FIG. 1I. This leaves the remainer of the columns unaffected by the doping process.

In some implementations, the projected range (Rp) of the boron can be approximately 15 nanometers (nm). The projected range refers to the average depth into a column and/or into a particular layer of the implanted (boron) ions. The projected range can be controlled based on, for example, the acceleration energy (e.g., measured in electron volts or eV) applied to the dopant ions. Electron volts are units of energy used in atomic and nuclear physics which are equal to the energy gained by an electron (a charged particle carrying unit electronic charge) when the electrical potential at the electron increases by one volt. In other implementations, the projected range of the boron can be greater or less than 15 nanometers. The projected range can depend on the thickness of the oxide layer(s), nitride layer(s) or any other materials deposited on the target polysilicon layer. The projected range can also depend on the desired depth or shallowness of the boron inside the silicon layer. By adding additional holes via the angled boron injection, the doped polysilicon can enable a relatively better erase operation for the column.

In some implementations, the dopant (e.g., boron) can be implanted during any before or after any manufacturing operation once polysilicon layer 130D is deposited. For example, the boron can be implanted on assembly 101E, on assembly 101F, on assembly 101J, etc.

Referring to FIG. 1J, a representation of a ninth operation is shown. In some implementations, assembly 101J is formed performing one or more etch operations (e.g., wet etch operations) to remove nitride layer 130B and oxide layer 130C from assembly 101H. This exposes the polysilicon channels (e.g., polysilicon 130D).

Referring to FIG. 1K, a representation of a tenth operation is shown. In some implementations, assembly 101K is formed by performing one or more deposition operations to add polysilicon layer 160. A laser spike anneal process can then be performed on assembly 101J. Laser spike annealing refers to a high-temperature heat treatment technique that activates the dopants in silicon and repairs damage done during the implantation process.

Referring to FIG. 1L, a representation of an eleventh operation is shown. In some implementations, assembly 101L is formed by performing one or more deposition operations to oxide layer 162. In some implementations, oxide layer 162 can be a p-type nickel oxide layer added by, for example, a chemical vapor deposition process. In some implementations, oxide layer can be made from any other metal, conducting material, compound, alloy, of any combination thereof, such as, for example, cobalt, titanium, tungsten, aluminum, copper, aluminum-copper, etc.

Referring to FIG. 1M, a representation of a twelfth operation is shown. In some implementations, assembly 101N is formed by performing one or more annealing operations. The one or more annealing operations can include a silicidation anneal process that heats (via, for example, plasma) the oxide layer 162 and/or polysilicon layer 160 to a predetermined temperature. This can cause the metal of oxide layer 162 to react with the polysilicon layer 160, forming metal-silicide layer 164. In some implementations, the annealing operation can heat oxide layer 162 and/or polysilicon layer 160 to approximately 400 Celsius to form metal-silicide layer 164. In some implementations, metal-silicide layer 164 is formed by introducing a silicon-containing precursor, thus causing the precursor to react with the metal layer (e.g., oxide layer 162) to form metal-silicide layer 164. In some implementations, metal-silicide layer 164 can include nickel silicide (NiSi), cobalt disilicide (CoSi2), titanium disilicide (TiSi2), titanium nitride (TiN), tungsten, aluminum copper (AlCu), etc. In some implementations, metal-silicide layer 164 can be an n-type semiconductor.

In some implementations, metal-silicide layer 164 can be (lightly) n-type doped. In particular, the silicidation anneal process can push out the n-type dopants from the metal-silicide layer 164. By doping metal-silicide layer 164, the pushed-out n-type dopants are reintroduced to the layer (or a higher concentration of n-type dopants is added).

In some implementations, rather than performing the anneal process (and the deposition process to deposit oxide layer 162 and/or silicide layer 164), a deposition process can be performed to deposit a metallic layer, such as, for example, a ruthenium (Ru) layer, or any other suitable metal, alloy, or compound. The metallic layer can be deposited using, for example, physical vapor deposition.

Referring to FIG. 1N, a representation of a thirteenth operation is shown. In some implementations, assembly 101N is formed by performing one or more deposition operations to add polysilicon layer 166.

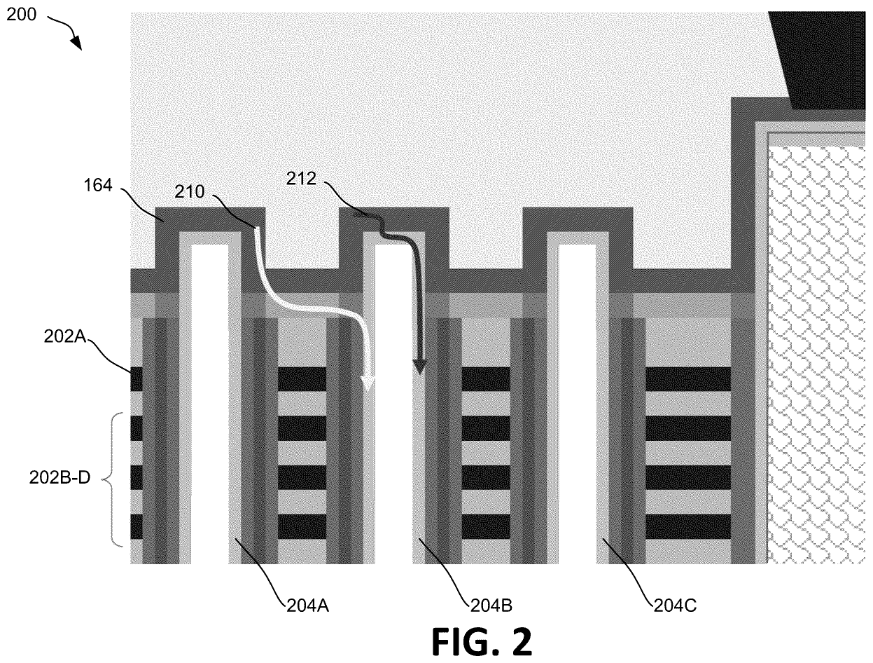

FIG. 2 is a diagram showing a sideview of the electron paths through assembly 101N, in accordance with some implementations of the present disclosure. In some implementations, in response to a particular wordline 202A-D having a positive charge from a voltage source, electrons can pass through path 210 to store data on a desired cell of a column (e.g., column 204B). In particular, a target cell can be represented by a particular wordline (e.g., wordline 202B) and a particular bitline (e.g., column 204B). To program the cell, the cell's respective wordline (e.g., wordline 202B) is set to a positive charge, then the cell's respective bitline is set to a target voltage (reflecting the data to be programmed to the cell). The allows the cell to store the target voltage. As shown, path 210 goes from metal-silicide layer 164 through the undoped side of column 204B.

To perform an erase operation, a negative voltage is applied to wordline 202A, thus providing (generating) holes through the doped region of one or more columns of assembly 101N. A positive voltage is then applied via the metal-silicide layer 164 (as shown by path 212 which goes from metal-silicide layer 164 through the doped side of column 204B). The positive voltage can be relatively high (e.g., 20 volts) such that the voltage is applied extracts electrons from the charge stored layer of the columns.

It is noted that in some implementations, the polarity of certain layers can be reversed. For example, metal-silicide layer 164 can be a p-type layer while the polysilicon layer of the columns (e.g., polysilicon layer 130D) can be implanted with a n-type dopant (e.g., phosphorus, arsenic, etc.).

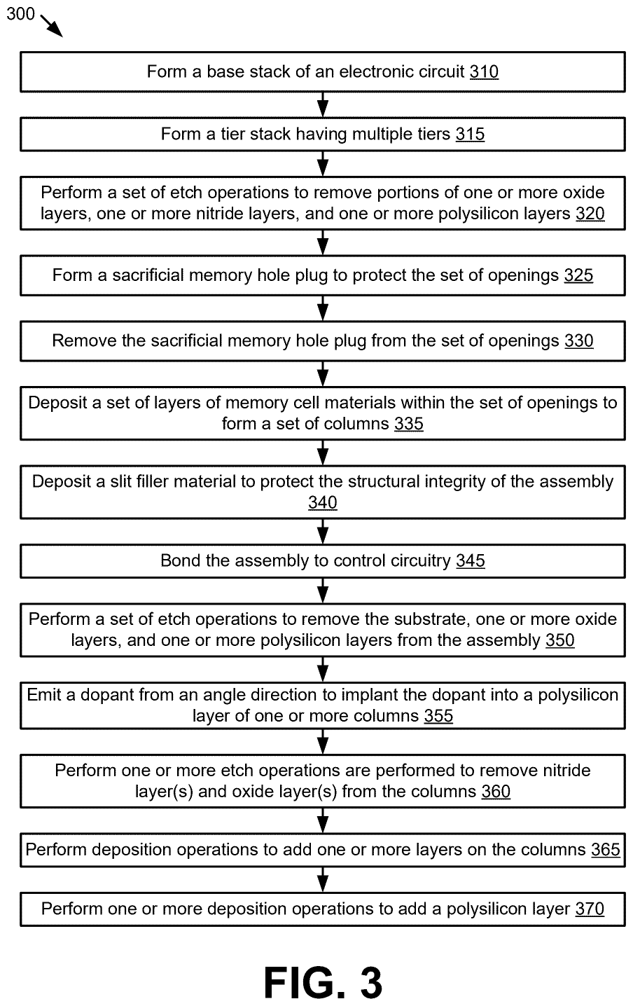

FIG. 3 is a flow diagram of an example method of manufacturing an electronic circuit (e.g., a memory array) to increase the depth of p-type region of silicon column during manufacturing, in accordance with some implementations of the present disclosure. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 310, a base stack of an electronic circuit is formed, the base stack including a base layer, oxide layers, and polysilicon layers. In an illustrative example, the base layer can include a semiconductor substrate. An oxide layer can then be deposited on the base layer, followed by a polysilicon layer, another oxide layer, and another polysilicon layer.

At block 315, a tier stack having multiple tiers is formed. For example, a set of tiers of alternating oxide layers and nitride layers is formed on top of the last polysilicon layer deposited at block 310. The tier stack can be formed by multiple deposition processes.

At block 320, a set of etch operations are performed to remove portions of one or more oxide layers, one or more nitride layers, and one or more polysilicon layers. The etch operations remove the layer portion to form a set of openings.

At block 325, a sacrificial memory hole plug is formed to protect the set of openings. For example, the set of openings can be filled with a certain material(s) (e.g., silicon, carbon, etc.) and planarized.

At block 330, the sacrificial memory hole plug is removed from the set of openings.

In some implementations, the sacrificial memory hole plug can be removed via one or more etch processes.

At block 335, a set of layers of memory cell materials is deposited within the set of openings to form a set of columns. The memory cell materials can include one or more layers of dielectric-barrier materials, charge-blocking materials, charge-storage materials, tunneling materials (e.g., gate-dielectric materials) and channel materials, etc.

At block 340, a slit filler material is deposited to protect the structural integrity of the assembly. The slit filler can include, for example, a polysilicon.

At block 345, the assembly is bonded to control circuitry. The bonding can include a fusion bonding process, a hybrid bonding process, etc. In some implementations, the top of the columns (e.g., the side of the columns opposite the substate) are bonded to the control circuitry.

At block 350, a set of etch operations are performed to remove the substrate, one or more oxide layers, and one or more polysilicon layers from the assembly. The set of etch operations can be used to expose a particular nitride layer and a particular polysilicon layer.

At block 355, a dopant is emitted from an angle direction to implant the dopant into a polysilicon layer of one or more columns. In some implementations, the dopant can be boron. The dopant can be implanted via an ion implementation process. The dopant can be emitted at a particular (predetermined) angle to increase the number of holes on a particular side of each column. In some implementations, the projected range of the dopant can be approximately 15 nanometers.

At block 360, one or more etch operations are performed to remove nitride layer(s) and oxide layer(s) from the columns. This exposes the (doped) polysilicon channels.

At block 365, one or more deposition operations are performed to add one or more layers on the columns. In some implementations, one or more layers can include a polysilicon layer and an oxide layer. In such implementations, one or more annealing operations can then be performed to heat the oxide layer and polysilicon layer such that the layers form a metal-silicide layer. In other implementations, the one or more layers can include a metallic layer.

At block 370, one or more deposition operations are performed to add a polysilicon layer.

FIG. 4A illustrates an example computing system 400 that includes a memory sub-system 410 in accordance with some embodiments of the present disclosure. In some embodiments, one or more components of computing system 400 include conductive lines manufactured according to a method described herein above. The memory sub-system 410 can include media, such as one or more volatile memory devices (e.g., memory device 440), one or more non-volatile memory devices (e.g., memory device 430), or a combination of such.

A memory sub-system 410 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 400 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 400 can include a host system 420 that is coupled to one or more memory sub-systems 410. In some embodiments, the host system 420 is coupled to multiple memory sub-systems 410 of different types. FIG. 4A illustrates one example of a host system 420 coupled to one memory sub-system 410. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 420 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 420 uses the memory sub-system 410, for example, to write data to the memory sub-system 410 and read data from the memory sub-system 410.

The host system 420 can be coupled to the memory sub-system 410 via a physical host interface. Examples of a physical host interface include a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 420 and the memory sub-system 410. The host system 420 can further utilize an NVM Express (NVMe) interface to access components (e.g., memory devices 430) when the memory sub-system 410 is coupled with the host system 420 by the physical host interface (e.g., PCIe bus). The physical host interface can provide an interface for passing control, address, data, and other signals between the memory sub-system 410 and the host system 420. FIG. 4A illustrates a memory sub-system 410 as an example. In general, the host system 420 can access multiple memory sub-systems via a same communication connection, multiple separate communication connections, and/or a combination of communication connections.

The memory devices 430, 440 can include any combination of the different types of non-volatile memory devices and/or volatile memory devices. The volatile memory devices (e.g., memory device 440) can be random access memory (RAM), such as dynamic random-access memory (DRAM) and synchronous dynamic random-access memory (SDRAM).

Some examples of non-volatile memory devices (e.g., memory device 430) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 430 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 430 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 430 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 430 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 415 (or controller 415 for simplicity) can communicate with the memory devices 430 to perform operations such as reading data, writing data, or erasing data at the memory devices 430 and other such operations. The memory sub-system controller 415 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 415 can be a microcontroller, special purpose logic circuitry (e.g., a field programmable gate array (FPGA), an application specific integrated circuit (ASIC), etc.), or other suitable processor.

The memory sub-system controller 415 can include a processing device, which includes one or more processors (e.g., processor 417), configured to execute instructions stored in a local memory 419. In the illustrated example, the local memory 419 of the memory sub-system controller 415 includes an embedded memory configured to store instructions for performing various processes, operations, logic flows, and routines that control operation of the memory sub-system 410, including handling communications between the memory sub-system 410 and the host system 420.

In some embodiments, the local memory 419 can include memory registers storing memory pointers, fetched data, etc. The local memory 419 can also include read-only memory (ROM) for storing micro-code. While the example memory sub-system 410 in FIG. 4A has been illustrated as including the memory sub-system controller 415, in another embodiment of the present disclosure, a memory sub-system 410 does not include a memory sub-system controller 415, and can instead rely upon external control (e.g., provided by an external host, or by a processor or controller separate from the memory sub-system).

In general, the memory sub-system controller 415 can receive commands or operations from the host system 420 and can convert the commands or operations into instructions or appropriate commands to achieve the desired access to the memory devices 430. The memory sub-system controller 415 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 430. The memory sub-system controller 415 can further include host interface circuitry to communicate with the host system 420 via the physical host interface. The host interface circuitry can convert the commands received from the host system into command instructions to access the memory devices 430 as well as convert responses associated with the memory devices 430 into information for the host system 420.

The memory sub-system 410 can also include additional circuitry or components that are not illustrated. In some embodiments, the memory sub-system 410 can include a cache or buffer (e.g., DRAM) and address circuitry (e.g., a row decoder and a column decoder) that can receive an address from the memory sub-system controller 415 and decode the address to access the memory devices 430.

In some embodiments, the memory devices 430 include local media controllers 435 that operate in conjunction with memory sub-system controller 415 to execute operations on one or more memory cells of the memory devices 430. An external controller (e.g., memory sub-system controller 415) can externally manage the memory device 430 (e.g., perform media management operations on the memory device 430). In some embodiments, memory sub-system 410 is a managed memory device, which is a raw memory device 430 having control logic (e.g., local media controller 435) on the die and a controller (e.g., memory sub-system controller 415) for media management within the same memory device package. An example of a managed memory device is a managed NAND (MNAND) device.

The memory sub-system 410 includes a memory interface component 413 that can handle interactions of memory sub-system controller 415 with the memory devices of memory sub-system 410, such as memory device 430. For example, memory interface component 413 can receive data from memory device 430, such as data retrieved in response to a read operation or a write operation. In some examples, the memory sub-system controller 415 can include a processor 417 (processing device) configured to execute instructions stored in local memory 419 for performing the operations described herein.

In some embodiments, memory device 430 includes a program manager 434. In some embodiments, local media controller 435 includes at least a portion of program manager 434 and is configured to perform various memory functions. In some embodiments, the program manager 434 is part of the host system 410, an application, or an operating system. Further details with regards to the operations of program manager 434 are described below. In some embodiments, program manager 434 is implemented on memory device 430 using firmware, hardware components, or a combination of the above.

FIG. 4B is a simplified block diagram of a first apparatus, in the form of a memory device 430, in communication with a second apparatus, in the form of a memory sub-system controller 415 of a memory sub-system (e.g., memory sub-system 410 of FIG. 4A), according to an embodiment. In some embodiments, one or more components of memory device 430 include conductive lines manufactured according to a method described herein above. Some examples of electronic systems include personal computers, personal digital assistants (PDAs), digital cameras, digital media players, digital recorders, games, appliances, vehicles, wireless devices, mobile telephones and the like. The memory sub-system controller 415 (e.g., a controller external to the memory device 430), can be a memory controller or other external host device.

Memory device 430 includes an array of memory cells 404 logically arranged in rows and columns. Memory cells of a logical row are typically connected to the same access line (e.g., a wordline) while memory cells of a logical column are typically selectively connected to the same data line (e.g., a bit line). A single access line can be associated with more than one logical row of memory cells and a single data line can be associated with more than one logical column. Memory cells (not shown in FIG. 4B) of at least a portion of array of memory cells 404 are capable of being programmed to one of at least two target data states.

Row decode circuitry 408 and column decode circuitry 411 are provided to decode address signals. Address signals are received and decoded to access the array of memory cells 404. Memory device 430 also includes input/output (I/O) control circuitry 412 to manage input of commands, addresses and data to the memory device 430 as well as output of data and status information from the memory device 430. An address register 414 is in communication with I/O control circuitry 412 and row decode circuitry 408 and column decode circuitry 411 to latch the address signals prior to decoding. A command register 424 is in communication with I/O control circuitry 412 and local media controller 435 to latch incoming commands.

A controller (e.g., the local media controller 435 internal to the memory device 430) controls access to the array of memory cells 404 in response to the commands and generates status information for the external memory sub-system controller 415, i.e., the local media controller 435 is configured to perform access operations (e.g., read operations, programming operations and/or erase operations) on the array of memory cells 404. The local media controller 435 is in communication with row decode circuitry 408 and column decode circuitry 411 to control the row decode circuitry 408 and column decode circuitry 411 in response to the addresses. In at least one embodiment, local media controller 435 includes program manager 434, which can implement the bad block mapping operations with respect to memory device 430, as described herein.

The local media controller 435 is also in communication with a cache register 418. Cache register 418 latches data, either incoming or outgoing, as directed by the local media controller 435 to temporarily store data while the array of memory cells 404 is busy writing or reading, respectively, other data. During a programming operation (e.g., a write operation), data can be passed from the cache register 418 to the data register 421 for transfer to the array of memory cells 404; then new data can be latched in the cache register 418 from the I/O control circuitry 412. During a read operation, data can be passed from the cache register 418 to the I/O control circuitry 412 for output to the memory sub-system controller 415; then new data can be passed from the data register 421 to the cache register 418. The cache register 418 and/or the data register 421 can form (e.g., can form a portion of) a page buffer of the memory device 430. A page buffer can further include sensing devices (not shown in FIG. 4B) to sense a data state of a memory cell of the array of memory cells 404, e.g., by sensing a state of a data line connected to that memory cell. A status register 422 can be in communication with I/O control circuitry 412 and the local memory controller 435 to latch the status information for output to the memory sub-system controller 415.

Memory device 430 receives control signals at the memory sub-system controller 415 from the local media controller 435 over a control link 432. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over control link 432 depending upon the nature of the memory device 430. In at least one embodiment, memory device 430 receives command signals (which represent commands), address signals (which represent addresses), and data signals (which represent data) from the memory sub-system controller 415 over a multiplexed input/output (I/O) bus 436 and outputs data to the memory sub-system controller 415 over I/O bus 436.

For example, the commands can be received over input/output (I/O) pins [7:0] of I/O bus 436 at I/O control circuitry 412 and can then be written into command register 424. The addresses can be received over input/output (I/O) pins [7:0] of I/O bus 436 at I/O control circuitry 412 and can then be written into address register 414. The data can be received over input/output (I/O) pins [7:0] for an 8-bit device or input/output (I/O) pins [15:0] for a 16-bit device at I/O control circuitry 412 and then can be written into cache register 418. The data can be subsequently written into data register 421 for programming the array of memory cells 404.

In at least one embodiment, cache register 418 can be omitted, and the data can be written directly into data register 421. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 430 by an external device (e.g., the memory sub-system controller 415), such as conductive pads or conductive bumps as are commonly used.

In some implementations, additional circuitry and signals can be provided, and that the memory device 430 of FIG. 4B has been simplified. It should be recognized that the functionality of the various block components described with reference to FIG. 4B cannot necessarily be segregated to distinct components or component portions of an integrated circuit device. For example, a single component or component portion of an integrated circuit device could be adapted to perform the functionality of more than one block component of FIG. 4B. Alternatively, one or more components or component portions of an integrated circuit device could be combined to perform the functionality of a single block component of FIG. 4B. Additionally, while specific I/O pins are described in accordance with popular conventions for receipt and output of the various signals, it is noted that other combinations or numbers of I/O pins (or other I/O node structures) can be used in the various embodiments.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure can be practiced without these specific details. In other instances, well-known components or methods are not described in detail or are presented in simple block diagram format in order to avoid unnecessarily obscuring the present disclosure. Thus, the specific details set forth are merely exemplary. Particular embodiments can vary from these exemplary details and still be contemplated to be within the scope of the present disclosure.

As used herein, the singular forms “a,” “an,” and “the” include plural references unless the context clearly indicates otherwise. Thus, for example, reference to “a precursor” includes a single precursor as well as a mixture of two or more precursors; and reference to a “reactant” includes a single reactant as well as a mixture of two or more reactants, and the like.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%, such that “about 10” would include from 9 to 11.

The term “at least about” in connection with a measured quantity refers to the normal variations in the measured quantity, as expected by one of ordinary skill in the art in making the measurement and exercising a level of care commensurate with the objective of measurement and precisions of the measuring equipment and any quantities higher than that. In certain embodiments, the term “at least about” includes the recited number minus 10% and any quantity that is higher such that “at least about 10” would include 9 and anything greater than 9. This term can also be expressed as “about 10 or more.” Similarly, the term “less than about” typically includes the recited number plus 10% and any quantity that is lower such that “less than about 10” would include 11 and anything less than 11. This term can also be expressed as “about 10 or less.”.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

Although the operations of the methods herein are shown and described in a particular order, the order of the operations of each method can be altered so that certain operations can be performed in an inverse order or so that certain operation can be performed, at least in part, concurrently with other operations. In another embodiment, instructions or sub-operations of distinct operations can be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A method, comprising:
forming an alternating layer stack of an electronic circuit, the alternating layer stack comprising a plurality alternating conductive and dielectric layers;
forming a set of memory cell columns in the alternating layer stack, wherein a bottom side of the set of memory cell columns is bonded to control circuitry; and
doping, with a dopant, a top side of the set of memory cell columns, wherein the doping is performed by emitting the dopant toward the top side of the set of memory cell columns at a predetermined angle to form a doped region of material in each memory cell column of the set of memory cell columns.

2. The method of claim 1, wherein the dopant comprises boron.

3. The method of claim 1, wherein one side of each memory cell column of the set of memory cell columns is doped.

4. The method of claim 1, wherein the top side of the set of memory cell columns is connected to a metal-silicide layer.

5. The method of claim 4, wherein the metal-silicide layer is doped.

6. The method of claim 1, wherein the top side of the set of memory cell columns is connected to a metal layer.

7. The method of claim 1, wherein, in response to a wordline of the electronic circuit experiencing a charge, a plurality of holes are generated through a doped side of one or more memory cell columns of the set of memory cell columns.

8. An electronic circuit, comprising:
a set of alternating layer stack comprising a plurality alternating conductive and dielectric layers; and
a set of memory cell columns in the alternating layer stack, wherein a bottom side of the set of memory cell columns is bonded to control circuitry, wherein a respective top side of each memory cell column of the set of memory cell columns is doped with a dopant at a predetermined angle to form a doped region of material.

9. The electronic circuit of claim 8, wherein the dopant comprises boron.

10. The electronic circuit of claim 8, wherein one side of each memory cell column of the set of memory cell columns is doped.

11. The electronic circuit of claim 8, wherein the top side of the set of memory cell columns is connected to a metal-silicide layer.

12. The electronic circuit of claim 11, wherein the metal-silicide layer is doped.

13. The electronic circuit of claim 8, wherein the top side of the set of memory cell columns is connected to a metal layer.

14. The electronic circuit of claim 8, wherein, in response to a wordline of the electronic circuit experiencing a charge, a plurality of holes are generated through a doped side of one or more memory cell columns of the set of memory cell columns.

15. A method, comprising:
applying a first voltage to a wordline of an electronic circuit; and
applying a second voltage to a memory cell column of the electronic circuit, wherein the memory cell column comprises a bottom side bonded to control circuitry and a top side doped with a dopant at a predetermined angle to form a doped region of material, wherein the second voltage travels through a doped side of the memory cell column to perform an erase operation on the electronic circuit.

16. The method of claim 15, wherein the dopant comprises boron.

17. The method of claim 15, wherein one side of each memory cell column of the set of memory cell columns is doped.

18. The method of claim 15, wherein the top side of the set of memory cell columns is connected to a metal-silicide layer.

19. The method of claim 18, wherein the metal-silicide layer is doped.

20. The method of claim 15, wherein the top side of the set of memory cell columns is connected to a metal layer.
